(19) United States
(12) Patent Application Publication
(10) Pub. No.: US 2018/0292443 A1
(43) Pub. Date: Oct. 11, 2018

(54) LEAKAGE CURRENT PROTECTION DEVICE

(71) Applicant: Chengli LI, Suzhou (CN)

(72) Inventor: Chengli LI, Suzhou (CN)

(21) Appl. No.: 15/595,008

(22) Filed: May 15, 2017

(30) Foreign Application Priority Data
Apr. 6, 2017 (CN) 201710219912.1
Apr. 6, 2017 (CN) 201720355793.8

(51) Int. Cl. G01R 31/02; H02H 3/33; G01R 31/28; G01R 31/42; H03K 5/24

(52) U.S. Cl. CPC G01R 31/025; H02H 3/335; H03K 5/24; G01R 31/42; G01R 31/2813

(57) ABSTRACT

A leakage current detection device which includes a switching unit for controlling electrical connection between an input end and an output end; a leakage current detection unit, including a plurality of current carrier wires and at least one leakage current detection wire, the leakage current detection wire being configured to detect whether a leakage current exists in any one of the plurality of current carrier wires; and a temperature monitoring unit, including at least one temperature-sensitive resistive element disposed at a temperature monitoring location, the temperature-sensitive resistive element being coupled to the switching unit via the leakage current detection wire and controlling the switching unit based on a temperature at the temperature monitoring location. By providing the temperature monitoring circuit, the leakage current protection device can prevent the appliance form being in a high temperature condition for prolonged time period, greatly improving safety of the appliance.

### BACKGROUND OF THE INVENTION

### Field of the Invention

This invention relates to electrical appliances, and in particular, it relates to a circuit interrupter device for over-temperature protection for home electrical appliances.

### Description of Related Art

With the wide use of home electrical appliances, their safety is important. Currently, most home electrical appliances are equipped with a protection device (circuit interrupters) such as leakage current protection plug. However, there are still problems. When electrical components within an appliance are defective or aged, or malfunction, temperature inside the appliance may rise, eventually even causing fire, bringing great harm to persons and property. Currently, some appliances are provided with temperature sensors using temperature-sensitive metal plates. However, temperature-sensitive metal plates have relatively high cost and are inconvenient to install.

Therefore, there is a need for a leakage current protection device with over-temperature protection that is easy to install and low cost.

### SUMMARY

Accordingly, the present invention is directed to a leakage current protection device that has a temperature detection circuit, which improves safety of the electrical appliance.

To achieve the above objects, the present invention provides a leakage current protection device, which includes: a switching unit, for controlling electrical connection between an input end and an output end of the leakage current detection device; a leakage current detection unit, including a plurality of current carrier wires and at least one leakage current detection wire, the leakage current detection wire being configured to detect whether a leakage current exists in any one of the plurality of current carrier wires; and a temperature monitoring unit, including at least one temperature-sensitive resistive element disposed at a temperature monitoring location, wherein the temperature-sensitive resistive element is coupled to the switching unit via the leakage current detection wire, and wherein the temperature monitoring unit controls the switching unit based on a temperature at the temperature monitoring location.

In one embodiment, the temperature monitoring unit further includes a first circuit, wherein one end of the first circuit is coupled to one of the plurality of current carrier wires, another end of the first circuit is coupled to the temperature-sensitive resistive element via the leakage current detection wire, and wherein the temperature-sensitive resistive element is coupled to another one of the plurality of current carrier wires.

In one embodiment, the at least one temperature-sensitive resistive element is a thermistor.

In one embodiment, when the temperature at the temperature monitoring location is higher than a predetermined threshold temperature, a resistance value of the thermistor increases or decreases to a resistance value that is configured to cause the switching unit to disconnect the electrical connection between the input end and the output end.

In one embodiment, the first circuit includes a first resistor and a first diode, the first resistor being coupled to the leakage current detector wire via the first diode, and wherein the at least one temperature-sensitive resistive element is coupled to the other one of the plurality of current carrier wires via at least one other diode.

In one embodiment, a plurality of temperature-sensitive resistive elements are coupled to the same or different ones of the plurality of current carrier wires.

In one embodiment, the temperature monitoring unit is coupled to a control terminal of a switching element of the switching unit, for controlling electrical connection between the input end and the output end.

In one embodiment, the switching element is a silicon-controlled rectifier, which is configured to be triggered into a conductive state by a drive signal generated by the leakage current detection unit and/or the temperature monitoring unit.

In another aspect, the present invention provides an electrical connection device which includes the above leakage current detection device, and further includes: an input interface for electrically connecting to a power source at the input end; and an output interface, for electrically connecting to an electrical appliance at the output end, wherein when at least one of the current carrier wires has a current leak or when the temperature at the temperature monitoring location exceeds a predetermined temperature, the switching unit disconnects the electrical connection between the power source and the electrical connection device.

In another aspect, the present invention provides an electrical appliance which includes the above leakage current detection device, and further includes: a plug for plugging into a power source, wherein when at least one of the current carrier wires has a current leak or when the temperature at the temperature monitoring location exceeds a predetermined temperature, the switching unit disconnects the electrical connection between the power source and the electrical appliance.

Embodiments of the present invention provide a temperature monitoring circuit in the leakage current protection device to monitor a high temperature condition in the appliance. This prevents the appliance from being in a high temperature condition for prolonged time period, greatly improving safety of the appliance.

### BRIEF DESCRIPTION OF THE DRAWINGS

Embodiments of the invention are described with reference to the following drawings. These drawings illustrates the working principles of the embodiments and do not limit the scope of the invention. The drawings are not to scale. In the drawings, similar components are designated with similar reference symbols.

FIG. 1 is a circuit diagram showing a first embodiment of the present invention.

FIG. 2 is a circuit diagram showing a second embodiment of the present invention.

FIG. 3 is a circuit diagram showing a third embodiment of the present invention.

FIG. 4 is a circuit diagram showing a fourth embodiment of the present invention.

### DETAILED DESCRIPTION OF PREFERRED EMBODIMENTS

Embodiments of the present invention are described with reference to the drawings. The drawings illustrate the embodiments of the present invention, but are not intended to be limiting. It will be apparent to those skilled in the art that, without departing from the spirit of the invention, other embodiments may be used, and structural or logical modification and variations can be made. Thus, it is intended that the present invention cover modifications and variations that come within the scope of the appended claims and their equivalents.

In embodiments of the present invention, thermistors, whose resistance values vary with temperature, are provided within electrical appliances in places or inside components that are at risk of high temperature. The number and locations of the thermistors may be determined based on evaluation of the appliance. When the temperature at the location of a thermistor reaches a predetermined value, due to change in resistance value of the thermistor, a leakage current signal is generated and is detected by a circuit of the leakage current protection device, causing the leakage current protection device to disconnect the appliance from the electrical power source, so as to protect the safety of the user and property.

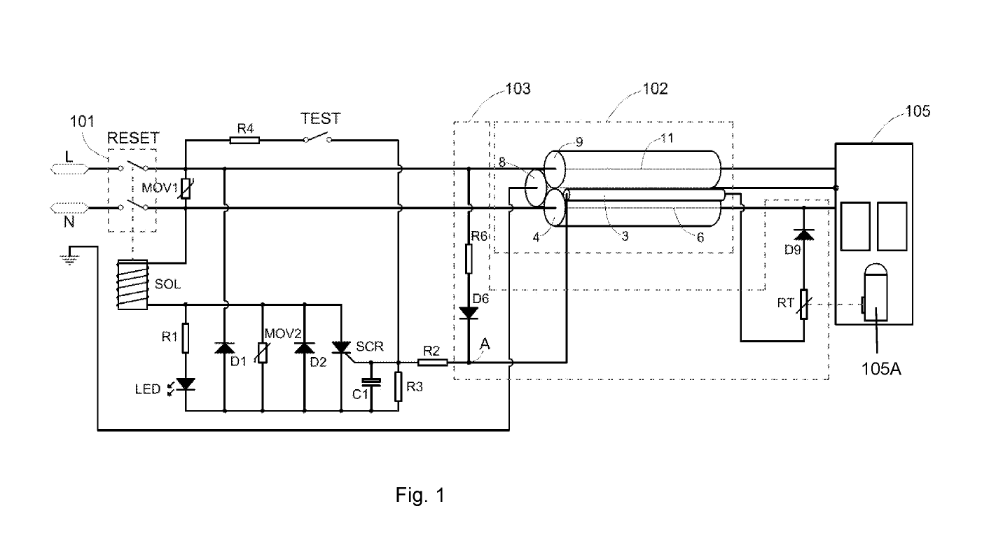

By providing temperature monitoring, the device can prevent high temperatures within the appliance due to malfunction or defects of the appliance. The structures and operation principles of the embodiments are described below with reference to FIGS. 1-4.

As shown in FIG. 1, the leakage current protection device (circuit interrupter) includes: (1) Switching unit 101, which includes a reset switch RESET disposed on the neutral (N) and hot (L) power lines. The reset switch is controlled by the solenoid SOL to electrically connect or disconnect the input end and output end of the leakage current protection device. (2) Leakage current detection unit 102, which includes current carrier wires 6 (neutral), 8 (ground) and 11 (hot), and leakage current detection wire 3 for detecting current leakage in the current carrier wires. (3) Temperature monitoring unit 103, which includes a first circuit including resistor R6 and diode D6, and a second circuit including thermistor RT and diode D9. The first circuit is coupled to the hot line L and to the control electrode of a silicon-controlled rectifier SCR via resistor R2; the first circuit is also coupled to the neutral line N via the leakage current detection wire 3 and the second circuit. At least a part of the temperature monitoring unit 103, such as the thermistor RT, is disposed at a monitoring location of the appliance 105, e.g. a compressor 105A in this example. A characteristic of the thermistor RT is that its resistance value increases with increasing temperature.

Current carrier wires 6, 8 and 11 are respectively covered with insulating layers (e.g. rubber, plastic, etc.). The current carrier wires 6 and 11 are further covered with a conductive layer (e.g. metal) 4 and 9 respectively outside the insulating layer, where the leakage current detection wire 3 is disposed between the metal conductive layers 4 and 9 and is in physical contact with them. In one embodiment, another metal conductive layer is provided outside the leakage current detection wire 3, the metal conductive layers 4 and 9, and the insulating layer of the current carrier wire 8, to cover them and shield them from the environment.

Based on the above described structure, the voltage at the control electrode of the SCR will be influenced by the resistance of the thermistor RT. The working process of the leakage current detection device is as follows.

1) When temperature at the monitoring location is normal

In this condition, i.e. the appliance functions normally, the first circuit and the second circuit form a current loop. Because the resistance of the thermistor RT is relatively how in this condition, the voltage at point A (between R2 and D6) is relatively low, so the SCR is not triggered to conduct. The input and output ends of the leakage current protection device are electrically connected, and the appliance is powered normally.

2) When temperature at the monitoring location is high

When the appliance experience a high temperature at the monitoring location (e.g. the compressor where the thermistor is located) due to malfunction or defects, when the temperature increases to reach the predetermined temperature, the resistance of thermistor RT increases to a predetermined resistance value such that the voltage at point A is sufficiently high to trigger the SCR into a conductive state. As a result, a large current flows through the solenoid SOL, causing the reset switch RESET to trip. This cuts off the electrical connection between the input and output ends, preventing the temperature of the appliance from increasing further or causing fire.

3) When a leakage current exist

Where there is a current leak between any two of current carrier wires 6, 8 and 11, the leakage can be detected via the leakage current detection wire 3 and the metal covers 4 and 9, so the leakage current detection wire 3 will carry electricity. A forward voltage drop is therefore formed across resistor R3, triggering SCR into a conductive state. As a result, a large current flows through the solenoid SOL, causing the reset switch RESET to trip. This cuts off the electrical connection between the input and output ends. When there is no leakage current on the leakage current detection wire 3, the SCR will not become conductive.

From the connection and polarities of diodes D6 and D9 shown in FIG. 1, it can be seen that the first circuit and the second circuit can form a current loop during the positive half cycles of the AC power. If their polarities are reversed, they can form a current loop during the negative half cycles. In the latter case, the resistor R6 and/or R9 should be set such that the SCR will not be triggered into the conductive state when there is no leakage current and no over-temperature condition.

It should be understood that in other embodiments, the first circuit can be coupled to the neutral line N, and correspondingly, the second circuit can be coupled to the hot line L.

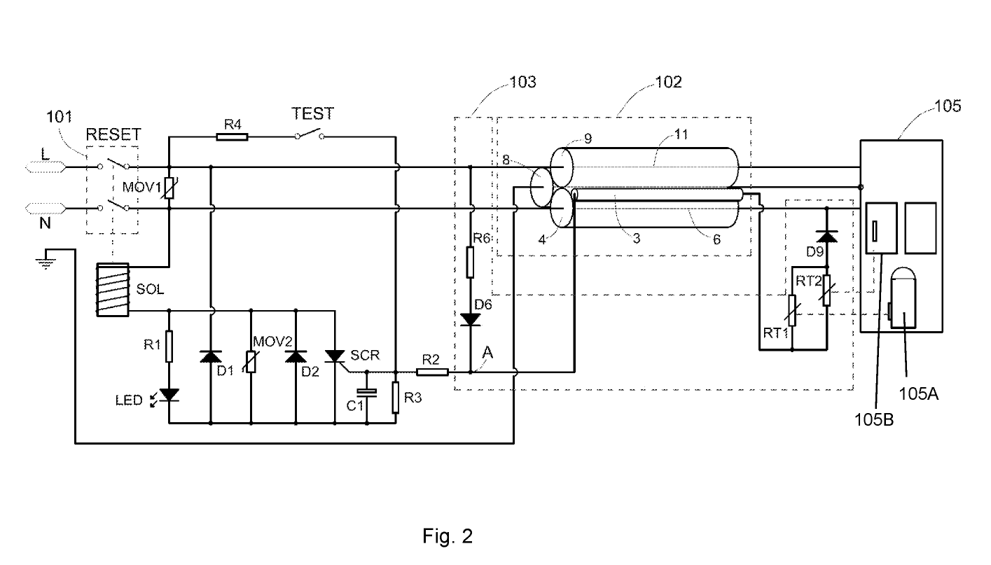

It should be understood that the thermistor can be located at any suitable location of the appliance. FIG. 2 is a circuit diagram showing a second embodiment of the present invention.

Compared to the circuit of FIG. 1, the leakage current protection device of FIG. 2 includes a first thermistor RT1 located on the compressor 105A, and further includes a second thermistor RT2 located on a control board 105B of the appliance 105, and the two thermistors RT1 and RT2 are coupled in parallel. Thus, when the temperature of the control board and/or compressor increases, the combined resistance of the parallel connected thermistors RT1 and RT2 will increase, which raises the voltage at point A.

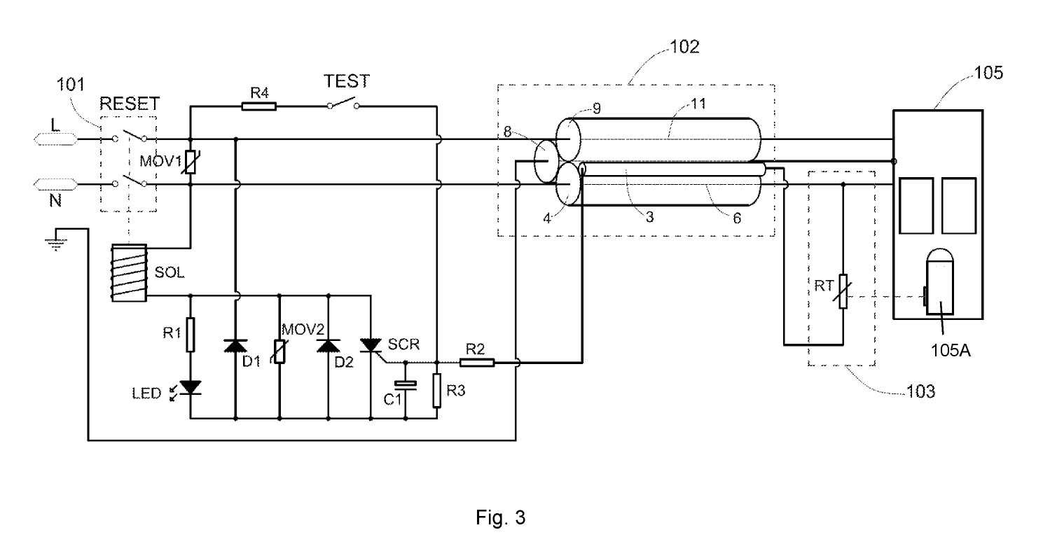

FIG. 3 is a circuit diagram showing a third embodiment of the present invention. In this embodiment, the characteristic of thermistor RT is that its resistance value decreases with increasing temperature.

As shown in FIG. 3, the temperature monitoring unit 103 includes thermistor RT, which is located at a location of the appliance 105 that is exposed to risk of high temperature, such as compressor or transformer or control circuit. The thermistor is coupled at one end to the neutral line N, and coupled at the other end to the control electrode of the SCR via the leakage current detection wire 3 and resistor R2. Thus, the voltage at the control electrode of the SCR is determined by the resistance values of resistor R3, resistor R2 and thermistor RT.

When the appliance 105 functions normally, the thermistor has a high resistance, so the voltage on resistor R3 is not sufficient to trigger the SCR into a conductive state. As a result, the input and out ends are electrically connected. When the appliance malfunctions or is defective causing a high temperature at the location of the thermistor RT, and the temperature reaches a predetermined value, the resistance of thermistor RT will decrease to a sufficiently low value, causing the voltage on resistor R3 to increase to a value sufficient to trigger the SCR into a conductive state. As a result, a large current flows through the solenoid SOL, causing the reset switch RESET to trip, which electrically disconnects the input and output ends, preventing further temperature increase of the appliance 105.

Similarly, the leakage current protection device may include additional thermistors, which may be connected in parallel and then to the neutral line N. In other embodiments, the thermistors may alternatively be coupled to the hot line L.

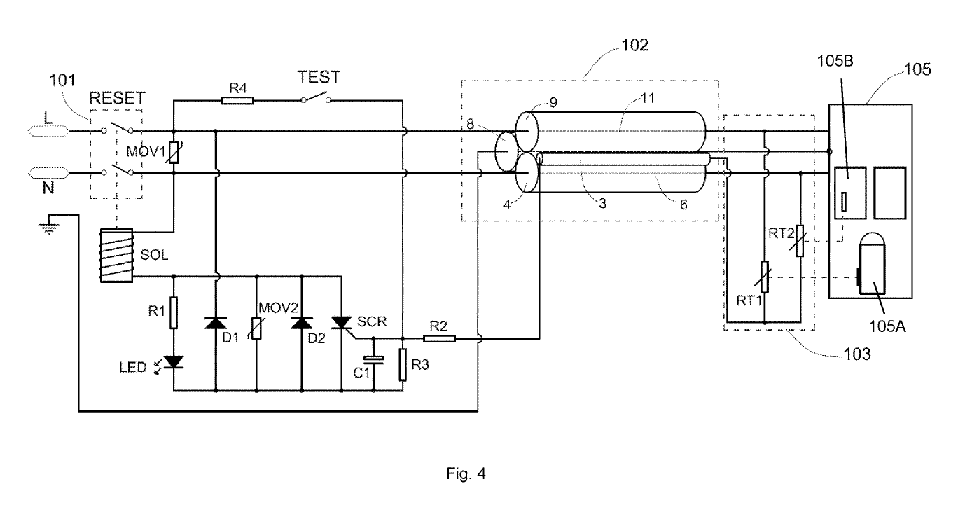

FIG. 4 is a circuit diagram showing a fourth embodiment of the present invention. In this embodiment, the characteristic of thermistors RT4 and RT5 is that their resistance values decreases with increasing temperature.

The thermistors RT4 and RT5 are respectively located on the compressor and control board of the appliance. One ends of thermistors RT4 and RT5 are respectively coupled to the hot line L and neutral line N, and the other ends of them are coupled to the control electrode of the SCR via the leakage current detection wire 3 and resistor R2. Thus, the voltage at the control electrode of the SCR is the voltage on resistor R3.

When the appliance 105 functions normally, the thermistors RT4 and RT5 have high resistance values, so the voltage on resistor R3 is not sufficient to trigger the SCR into a conductive state. As a result, the input and out ends are electrically connected.

When the appliance malfunctions or is defective causing a high temperature at the location of thermistor RT4 and/or RT5; when the temperature reaches predetermined values for RT4 and/or RT5, the resistance of thermistor RT4 and/or RT5 will decrease to a sufficiently low value, causing a trigger signal to be applied to the control electrode of the SCR from the hot line L or neutral line N to trigger the SCR into a conductive state. As a result, a large current flows through the solenoid SOL, causing the reset switch RESET to trip, which electrically disconnects the input and output ends, preventing further temperature increase of the appliance.

In summary, embodiments of the present invention provide a temperature monitoring circuit in the leakage current protection device to monitor a high temperature condition in the appliance. This prevents the appliance form being in a high temperature condition for prolonged time period, greatly improving safety of the appliance.

Another embodiment of the present invention is an electrical connection device that employs the above described leakage current detection device. The electrical connection device further includes: an input interface for electrically connecting to a power source at the input end, and an output interface, for electrically connecting to an appliance at the output end. When at least one current carrier wire has a leak, a leakage current detection unit will cause the switch unit to disconnect the electrical connection between the input interface and the output interface. When the temperature at the temperature monitoring location exceeds the predetermined temperature, the temperature monitoring unit will cause the switch unit to disconnect the electrical connection between the input interface and the output interface, to protect the appliance that is connected to the power source via the electrical connection device.

Another embodiment of the present invention is an electrical appliance that employs the above described leakage current detection device. The appliance includes a plug for plugging into the power source. When at least one current carrier wire has a leak, or the temperature at the temperature monitoring location exceeds the predetermined temperature, a leakage current detection unit or the temperature monitoring unit will cause the switch unit to disconnect the electrical connection between the input interface and the output interface.

It will be apparent to those skilled in the art that various modification and variations can be made in the leakage current detection device of the present invention without departing from the spirit or scope of the invention. Thus, it is intended that the present invention cover modifications and variations that come within the scope of the appended claims and their equivalents.

What is claimed is:

1. A leakage current detection device, comprising:
a switching unit, for controlling electrical connection between an input end and an output end of the leakage current detection device;
a leakage current detection unit, including a plurality of current carrier wires and at least one leakage current detection wire, the leakage current detection wire being configured to detect whether a leakage current exists in any one of the plurality of current carrier wires; and
a temperature monitoring unit, including at least one temperature-sensitive resistive element disposed at a temperature monitoring location, wherein the temperature-sensitive resistive element is coupled to the switching unit via the leakage current detection wire, and wherein the temperature monitoring unit controls the switching unit based on a temperature at the temperature monitoring location.

2. The leakage current detection device of claim 1, wherein the temperature monitoring unit further includes a first circuit, wherein one end of the first circuit is coupled to one of the plurality of current carrier wires, another end of the first circuit is coupled to the temperature-sensitive resistive element via the leakage current detection wire, and wherein the temperature-sensitive resistive element is coupled to another one of the plurality of current carrier wires.

3. The leakage current detection device of claim 1, wherein the at least one temperature-sensitive resistive element is a thermistor.

4. The leakage current detection device of claim 3, wherein when the temperature at the temperature monitoring location is higher than a predetermined threshold temperature, a resistance value of the thermistor increases or decreases to a resistance value that is configured to cause the switching unit to disconnect the electrical connection between the input end and the output end.

5. The leakage current detection device of claim 2, wherein the first circuit includes a first resistor and a first diode, the first resistor being coupled to the leakage current detector wire via the first diode, and wherein the at least one temperature-sensitive resistive element is coupled to the other one of the plurality of current carrier wires via at least one other diode.

6. The leakage current detection device of claim 1, comprising a plurality of temperature-sensitive resistive elements, coupled to the same or different ones of the plurality of current carrier wires.

7. The leakage current detection device of claim 1, wherein the temperature monitoring unit is coupled to a control terminal of a switching element of the switching unit, for controlling electrical connection between the input end and the output end.

8. The leakage current detection device of claim 7, wherein the switching element is a silicon-controlled rectifier, which is configured to be triggered into a conductive state by a drive signal generated by the leakage current detection unit and/or the temperature monitoring unit.

9. An electrical connection device comprising the leakage current detection device of claim 1, further comprising:
an input interface for electrically connecting to a power source at the input end; and
an output interface, for electrically connecting to an electrical appliance at the output end,
wherein when at least one of the current carrier wires has a current leak or when the temperature at the temperature monitoring location exceeds a predetermined temperature, the switching unit disconnects the electrical connection between the power source and the electrical connection device.

10. An electrical appliance comprising the leakage current detection device of claim 1, further comprising:
a plug for plugging into a power source,
wherein when at least one of the current carrier wires has a current leak or when the temperature at the temperature monitoring location exceeds a predetermined temperature, the switching unit disconnects the electrical connection between the power source and the electrical appliance.
